(19) United States
(12) Patent Application Publication
(10) Pub. No.: US 2015/0069322 A1
(43) Pub. Date: Mar. 12, 2015

(54) SEMIPOLAR EMITTER

(71) Applicant: Justin PAYNE, San Jose, CA (US)

(72) Inventor: Justin PAYNE, San Jose, CA (US)

(21) Appl. No.: 14/252,732

(22) Filed: Apr. 14, 2014

Related U.S. Application Data
(60) Provisional application No. 61/811,679, filed on Apr. 12, 2013.

(51) Int. Cl. H01L 33/00; H01L 33/32; H01L 33/18; H01L 33/06

(52) U.S. Cl. CPC H01L 33/0025; H01L 33/06; H01L 33/32; H01L 33/18
USPC 257/13

(57) ABSTRACT

A light emitting diode is disclosed in the form of a III-V compound semiconductor hetero-epitaxially grown on the (111) crystallographic surface of a silicon substrate. The light emitter consists of a multiple quantum well hetero-structure that has been realized in one or more crystallographic planes that are members of a set of semi-polar crystallographic planes of the III-V material.

### CROSS-REFERENCES TO RELATED APPLICATIONS

The present invention claims priority to U.S. Provisional Application No. 61/811,679, filed Apr. 12, 2013, which is incorporated by reference herein for all purposes.

### FIELD OF THE INVENTION

The described invention relates generally to the field of silicon integrated optoelectronics. More specifically, the described invention relates to the fields of general lighting, specialty illumination sources, proximity sensing, motion detection, color sensing, optical signal isolation and compound semiconductor power electronics.

### BACKGROUND OF THE INVENTION

This patent is related to multiple quantum well structures realized in electrically semi-polar crystal planes of a III-V material for the purpose of fabricating light emitting diodes. For many years light emitting diodes have been fabricated in the (0001) crystallographically oriented c-plane, an electrically polar crystal plane of GaN, utilizing various types of ternary multiple quantum well (MQW) structures which are crystallographically coherent with the c-plane. Examples of such c-plane oriented MQW structures are InGaN/GaN and AlGaN/GaN. Devices fabricated on electrically polar crystallographic planes or facets of GaN are fundamentally limited in their optical performance, specifically the efficiency of their light output power for a given electrical input power, by the physical confinement of electron and hole carrier pairs that contribute to radiative recombination. A reduction in the electrical polarization present in the MQW stack and surrounding thin film n-type and p-type material serves to improve device efficiency with respect to the electrical to optical power conversion. Specifically, less electrical polarization in the MQW layer stack results in lower magnitude of electric field and thus less physical confinement of electrons and holes, enabling more efficient radiative recombination and increased light output power for a given electrical input power.

### SUMMARY OF THE INVENTION

This patent discloses a light emitting diode fabricated in the (1-101) electrically semi-polar crystal planes of a wurtzite crystal structure III-V semiconductor hetero-epitaxial film that is deposited on the (111) crystal planes of a suitable silicon substrate. The device structure is comprised of a sequence of III-V compound semiconductor thin films. One specific example of such a III-V semiconductor is GaN. In one preferred embodiment of the invention the layer sequence is described as follows: First, a layer of n-GaN is deposited by metal-organic chemical vapor deposition (MOCVD) on a suitably prepared (111) crystal facet of a suitably processed silicon substrate. The n-GaN film is grown using appropriate MOCVD reactor conditions to express the semi-polar (1-101) crystal facet of the GaN hetero-epitaxial layer. The n-GaN can be doped with either Si or Ge, and provides a means of injecting electrons into the hetero-structure. Next the MQW structure is deposited on this (1-101) facet using appropriate reactor conditions to achieve the desired layer composition, quantum well thickness and barrier layer thickness. Specifically, a MQW structure comprised of an InGaN quantum well region bounded by a GaN barrier layer is considered as one preferred embodiment, although other choices of ternary and quaternary compound semiconductor alloys are possible. The existing n-GaN (1-101) crystallographic facet acts as a template for the MQW layer deposition, forcing crystallographic coherence between the two layers and resulting in a (1-101) oriented MQW hetero-structure. After MQW growth, a p-GaN layer is deposited to cap the structure. This p-GaN, usually doped with Mg, provides a means of injecting holes into the hetero-structure. Finally, n-type and p-type contacts are formed on the device structure through a series of lithography, etch, metal film deposition and cleaning steps which are commonly known in the art.

1. A light emitting diode (LED) comprised of a III-V compound semiconductor film stack where the electron—hole pair radiative recombination region is located in an electrically semi-polar crystal plane of the semiconductor film.

2. The light emitter in claim 1 where the III-V film is deposited on the (111) crystal facet of a suitably prepared silicon substrate.

3. The light emitter in claim 1 where the III-V film stack is comprised of GaN-based multiple quantum well hetero-structures.

4. The light emitter in claim 2 where the silicon substrate is a suitably patterned planar (111) orientation.

5. The emitter in claim 2 where the silicon substrate is a (100) orientation with suitably patterned (111) facets.

6. The emitter in claim 2 where the silicon substrate is a (110) orientation with suitably patterned (111) facets.

7. The light emitter in claim 1 where the III-Nitride MQW hetero-structures are oriented along the one of the set of (1-101) electrically semi-polar crystallographic planes of the Wurtzite crystal structure.

8. The light emitter in claim 1 where the GaN MQW hetero-structures are oriented along the one of the set of (1-102) electrically semi-polar crystallographic planes of the Wurtzite crystal structure.

9. The light emitter in claim 3 where the GaN-based MQW hetero-structures consist of InGaN/GaN layer stacks.

10. The light emitter in claim 3 where the GaN-based MQW hetero-structures consist of AlGaN/GaN layer stacks.

11. The light emitter in claim 1 where the III-V film stack is comprised of InN-based multiple quantum well hetero-structures.

12. The light emitter in claim 1 where the III-V film stack is comprised of AlN-based multiple quantum well hetero-structures.

13. The light emitter in claim 11 where the InN-based MQW hetero-structures consist of GaInN/InN layer stacks.

14. The light emitter in claim 11 where the InN-based MQW hetero-structures consist of AlInN/InN layer stacks.

15. The light emitter in claim 12 where the AlN-based MQW hetero-structures consist of GaAlN/AlN layer stacks.

16. The light emitter in claim 12 where the AlN-based MQW hetero-structures consist of InAlN/AlN layer stacks.
